(19) United States
(12) Patent Application Publication
(10) Pub. No.: US 2025/0285927 A1
(43) Pub. Date: Sep. 11, 2025

(54) METHOD OF MANUFACTURING ELECTRONIC COMPONENTS

(71) Applicant: STMicroelectronics International N.V., Geneva (CH)

(72) Inventors: Ludovic FOURNEAUD, Saint Vincent de Mercuze (FR); Jerome LOPEZ, Saint Jean De Moirans (FR); Didier SIGNORET, Polienas (FR)

(73) Assignee: STMicroelectronics International N.V., Geneva (CH)

(21) Appl. No.: 19/068,809

(22) Filed: Mar. 3, 2025

(30) Foreign Application Priority Data
Mar. 5, 2024 (FR) FR2402204

(51) Int. Cl. H01L 23/29; H01L 21/56; H01L 23/31; H01L 23/498; H01L 23/538

(52) U.S. Cl. CPC H01L 23/295; H01L 21/565; H01L 23/3135; H01L 23/49816; H01L 23/5386

(57) ABSTRACT

A hydrophobic electronic component is made using a process step where a hydrophobic coating is deposited on an electronic component. That electronic component includes a substrate, a chip positioned on a first side of the substrate, electric connection terminals positioned on a second side of the substrate, electric tracks running through the substrate, and a resin or a cover covering the first side of the substrate and the chip.

### PRIORITY CLAIM

This application claims the priority benefit of French Application for Patent No. 2402204, filed on Mar. 5, 2024, the content of which is hereby incorporated by reference in its entirety to the maximum extent allowable by law.

### TECHNICAL FIELD

The present disclosure concerns the manufacturing of electronic components and, more specifically, concerns the manufacturing of electronic components of package type.

### BACKGROUND

Package-type electronic components typically comprise one or a plurality of integrated circuit (IC) chips arranged on the front side of a substrate made of a non-conductive material. The chip(s) are protected from the external environment by a resin layer covering the front side of the substrate. Electric contact terminals are positioned on the back side of the substrate. Electric tracks run through the substrate and couple the chip(s) to the electric terminals.

To be able to be used in humid environments, these electronic components must have a high resistance to water and humidity.

To achieve such an aim, a solution is to use a ceramic substrate. However, with such substrates, it is not possible to miniaturize the components. Another solution would be to add an additional, environmentally-tight package, but this would increase the size of the electronic component and make its installation in a final product more difficult.

There exists a need to improve, at least partly, certain aspects of known electronic component manufacturing methods to obtain water-resistant and humidity-resistant electronic components which can be miniaturized.

### SUMMARY

An embodiment presents a method of manufacturing a hydrophobic electronic component comprising a step during which a hydrophobic coating is deposited on an electronic component comprising a substrate, a chip being positioned on a first side of the substrate, electric connection terminals being positioned on a second side of the substrate and being electrically coupled to the chip by means of electric tracks running through the substrate, a resin or a cover covering the first side of the substrate and the chip.

According to a specific embodiment, the method comprises the following steps: providing an element comprising a plurality of electronic components; separating the electronic components; bonding electric connection pads to the electric connection terminals; and depositing the hydrophobic coating so as to completely cover the electronic component.

According to a specific embodiment, the method further comprises a subsequent step during which the hydrophobic coating deposited on the electrical connection pads is removed.

According to a specific embodiment, the electric connection pads are protected during the deposition of the hydrophobic coating.

According to a specific embodiment, the method comprises the following steps: providing an element comprising a plurality of electronic components; depositing the hydrophobic coating so as to cover the resin or the cover and the second side of the substrate; carrying out a step during which the hydrophobic coating deposited on the electric terminals is removed; optionally, bonding electric connection pads to the electric terminals; and separating the electronic components.

According to a specific embodiment, the method comprises the following steps: providing an element comprising a plurality of electronic components; separating the electronic components; depositing the hydrophobic coating so as to fully cover the electronic component; carrying out a step during which the hydrophobic coating deposited on the electric terminals is removed; and optionally, bonding electric connection pads to the electric terminals.

According to a specific embodiment, the hydrophobic coating is a composite comprising a polymer material having fillers, preferably made of ceramic or of graphene, and even more preferably of alumina or of silica, dispersed therein.

According to a specific embodiment, the substrate is made of a resin, preferably an epoxy resin, or of a composite material comprising fillers, such as glass fibers, dispersed in a resin, preferably an epoxy resin.

An embodiment further relates to an electronic component comprising a substrate, a chip being positioned on a first side of the substrate, electric connection terminals being positioned on a second side of the substrate and being electrically coupled to the chip by means of electric tracks running through the substrate, a resin or a cover covering the first side of the substrate and the chip, a hydrophobic coating covering at least the resin or the cover and the second side of the substrate between the electric connection terminals.

According to a specific embodiment, the hydrophobic coating is a composite comprising a polymer material having fillers, preferably made of ceramic or of graphene, and even more preferably of alumina or of silica, dispersed therein.

According to a specific embodiment, the substrate is made of a resin, preferably an epoxy resin, or of a composite material comprising fillers, such as glass fibers, dispersed in a resin, preferably an epoxy resin.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A to 1E show cross-section views illustrating steps of a method of manufacturing an electronic component;

FIGS. 2A to 2E show cross-section views illustrating steps of a method of manufacturing an electronic component; and

FIGS. 3A to 3E show cross-section views illustrating steps of a method of manufacturing an electronic component.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

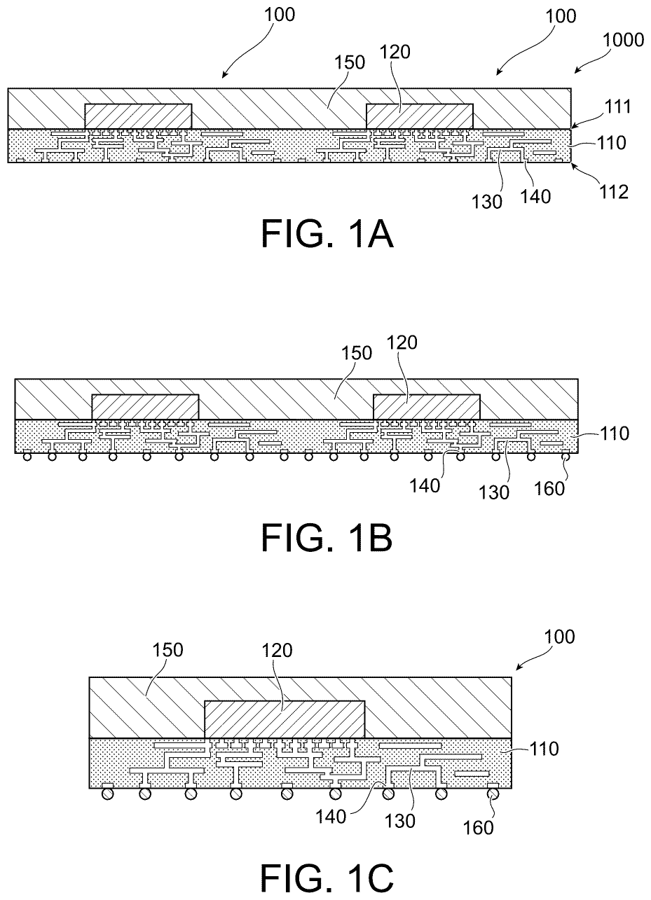

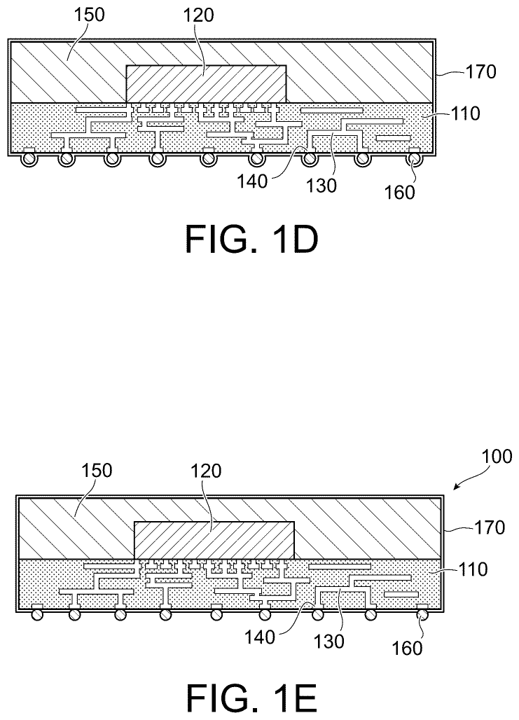

As shown in FIGS. 1A to 1E, FIGS. 2A to 2E, and FIGS. 3A to 3E, the method of manufacturing a hydrophobic electronic component 100 comprises at least one step during which a hydrophobic coating 170 is formed on an electronic component 100. Electronic component 100 comprises: a substrate 110; an integrated circuit (IC) chip 120 being positioned on a first side 111 of substrate 110, with electric connection terminals 140 being positioned on a second side 112 of substrate 110 and being electrically coupled to chip 120 by means of electric tracks 130 running through substrate 110; and a protective element 150, typically a resin or a cover, covering the first side 111 of substrate 110 and chip 120. The chip is, for example, BGA type chip mounted to the substrate 110 in a so-called “flip-chip” orientation, and the electric tracks 130 couple the lower surface of the chip 120 to the terminals 140.

Hydrophobic coating 170 protects electronic component 100 from the external environment, and in particular from water and humidity of the external environment.

The obtained resistance to water and humidity is comparable to that of a ceramic substrate. The lifetime of the component and its resistance to corrosion are thus improved.

The water and humidity resistance can be estimated, for example, in accordance with standard J-STD-033D.

More particularly, the method advantageously comprises at least the following steps:
a) providing an element 1000 comprising a plurality of electronic components 100, having a common substrate 110, each electronic component comprising one or a plurality of chips 120 arranged on the first side 111 of substrate 110, electric connection terminals 140 arranged on the second side 112 of substrate 110, electric tracks 130 coupling chip(s) 120 to electric connection terminals 140;
b) cutting substrate 110 between chips 120 to form individual electronic components 100; and
c) forming hydrophobic coating 170.

The steps may be carried out in different orders: a), b), and c) or a), c), and b). In other words, coating 170 may be applied before the singulation or after the singulation of components 100.

In the following, assemblies of ‘flip chip’ type, that is, assemblies with BGA (Ball Grid Array) components having connection pads 160 (‘bumps’) positioned under the chip, will more particularly be described, but it could be assemblies of ‘wire bond’ type, that is, assemblies with LGA (Land Grid Array) electronic components for which wires, for example made of gold, of silver, or of copper, are used to achieve the connection.

According to a first alternative embodiment shown in FIGS. 1A to 1E, the method comprises the following steps: a) providing an element 1000 comprising a plurality of electronic components 100 (FIG. 1A); d) bonding electric connection pads 160 to electric connection terminals 140 (FIG. 1B); b) cutting substrate 110 to separate the various electronic components 100 (FIG. 1C); and c) forming hydrophobic coating 170 (FIG. 1D).

During step c), the coating covers, preferably fully, electronic component 100. The coating may be formed in one or more steps.

According to this first alternative embodiment, the method may further comprise a step e) during which the hydrophobic coating 170 formed on electric connection pads is removed (FIG. 1E).

This removal step is, for example, carried out by chemical etching or by mechanical action, in particular by means of a polishing.

Alternatively, and still according to this first embodiment, the method may comprise a step during which electric connection pads 160 are protected by a protective element during the forming of hydrophobic coating 170.

After the deposition of hydrophobic coating 170, the protective element is removed. For example, if, during the deposition of hydrophobic coating 170, component 100 is positioned on an adhesive support by gluing connection pads 160 to this support, connection pads 160 will not be fully covered by coating 170. The adhesive support will be selected to be sufficiently soft to enable to partially sink the balls therein. This embodiment is also compatible with electronic components of LGA (Land Grid Array) type.

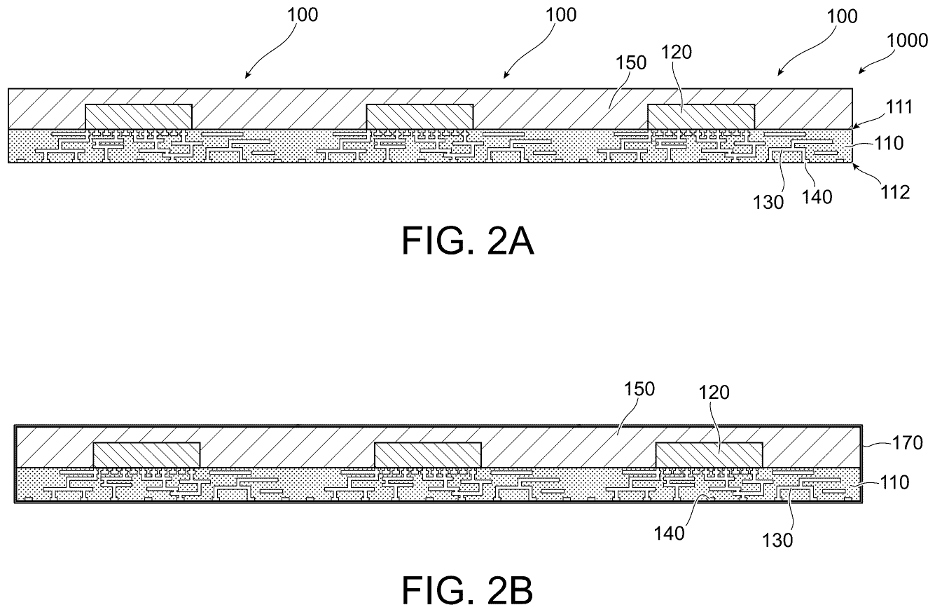

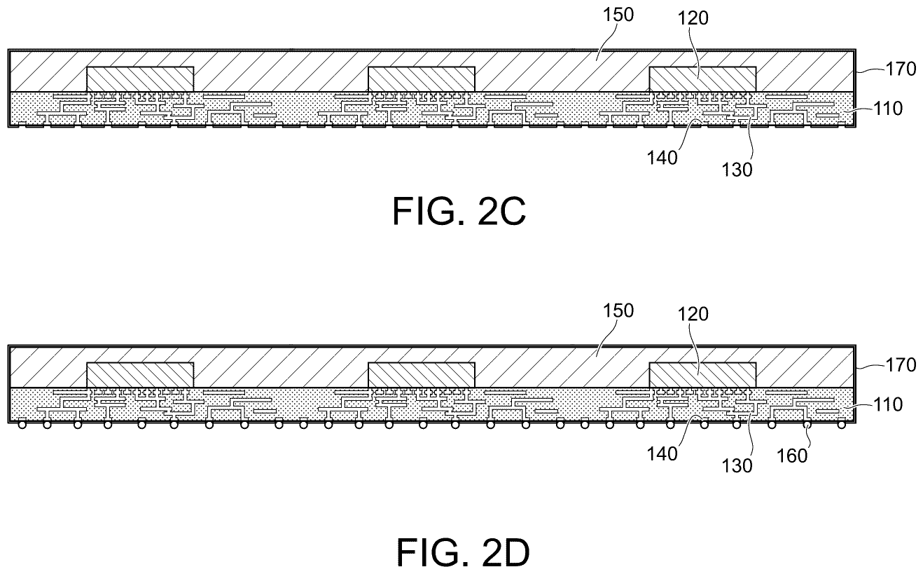

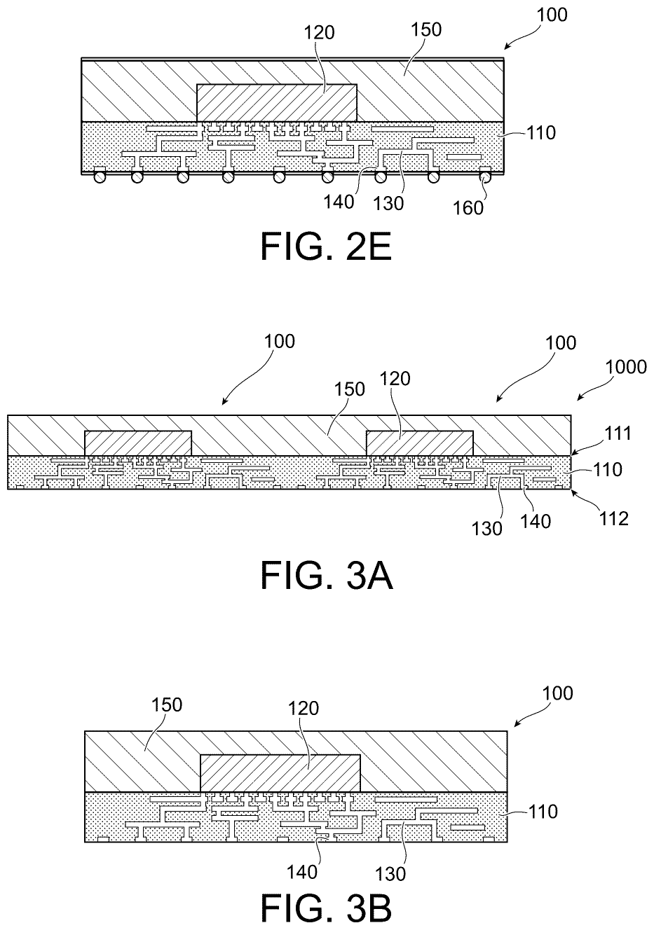

According to a second embodiment, shown in FIGS. 2A to 2E, the method comprises the following steps: a) providing an element 1000 comprising a plurality of electronic components 100 (FIG. 2A); c) depositing hydrophobic coating 170 on the resin and on the second side 112 of substrate 110 (FIG. 2B); e) carrying out a step during which the hydrophobic coating 170 deposited on electric terminals 140 is removed, for example by etching (FIG. 2C); d) preferably bonding electric connection pads 160 to electric terminals 140 (FIG. 2D); and b) separating the individual electronic components 100 (FIG. 2E).

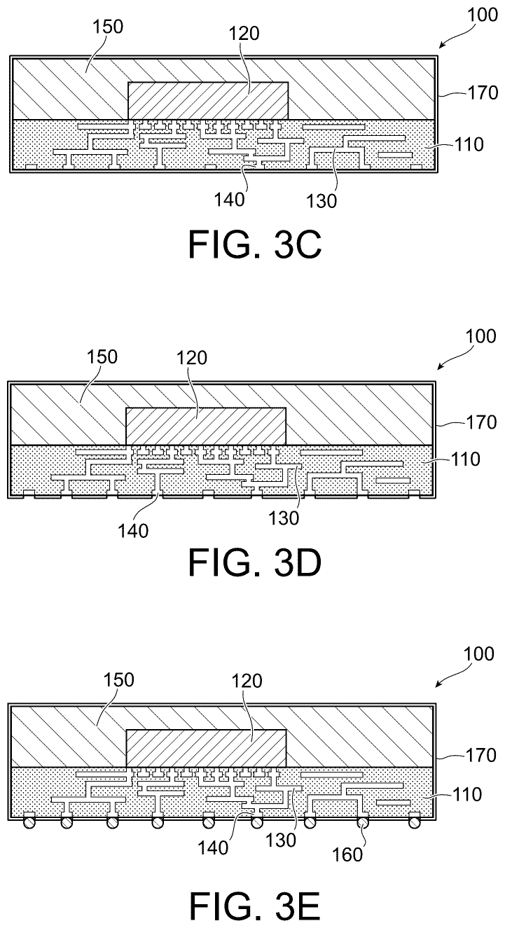

According to a third embodiment, shown in FIGS. 3A to 3E, the method comprises the following steps: a) providing an element 1000 comprising a plurality of electronic components 100 (FIG. 3A); b) separating the various electronic components 100 (FIG. 3B); c) Depositing hydrophobic coating 170 so as to fully cover the electronic component (FIG. 3C); e) etching hydrophobic coating 170 to make electric connection terminals 140 accessible (FIG. 3D); and d) optionally, bonding electric connection pads 160 to electric terminals 140 (FIG. 3E).

According to this third alternative embodiment, it is possible to manufacture electronic components of BGA (Ball Grid Array) type or of LGA (Land Grid Array) type, depending on the completion or not of step d).

The steps of these different alternative embodiments will be described in further detail.

The element 1000 provided at step a) comprises a plurality of electronic components 100, each electronic component 100 comprising at least one chip 120, a substrate 110, and a protective element 150. Substrate 110 is common to the various electronic components 100. Element 1000 preferably has a matrix format (‘BGA matrix’ or ‘LGA matrix’).

Chip 120 may comprise one discrete component or a plurality of discrete components. The discrete component(s) are, for example, selected from among transistors, diodes, thyristors, triacs, filters, etc. Chip 120 may comprise one or a plurality of electronic circuits. Chip 120 enables to implement various electronic functions. As an illustration, capacitors and inductors can be mentioned.

Electronic component 100 is a so-called integrated component.

At step a), the manufacturing of the discrete component(s) and/or integrated circuit(s) forming electronic components 100 is complete. Components 100 have not been singulated yet.

Substrate 110 comprises a first side 111 (upper surface or front surface) and a second side 112 (lower surface or rear surface).

Chips 120 are bonded to the first side 111 of substrate 110. In the drawings, a single chip 120 is shown for each component 100, but the electronic components may comprise a plurality of chips 120.

Substrate 110 comprises an electrically-insulating material having the electric tracks 130 formed therein. The electrically-insulating material may be a resin, a polymer, or a composite material comprising a resin or a polymer having non-conductive fillers, such as glass fibers, dispersed therein. The resin is preferably an epoxy-type resin.

Electric tracks 130 of substrate 110 run from the first side 111 of substrate 110 to the second side 112 of substrate 110, to allow the connection of chip 120 to an external device. Electric tracks 120 thoroughly cross substrate 110.

Tracks 130 are, for example, made of copper.

Electric connection terminals 140 (also known as electric connection pads or electric contacts) are positioned on the second side 112 of substrate 110. They are connected to the electric tracks 130 of substrate 110.

They are made of a conductive material specifically adapted to allowing the bonding of connection pads 160. Electric connection terminals 140 comprise at least one of the following elements: gold, titanium, nickel, copper, silver, tin, or tungsten. Preferably, they comprise gold or copper. They may be plated.

Preferably, substrate 110 and electric tracks 130 form a printed circuit board (PCB).

Chip 120 is protected by a protective element 150. It covers the first side 111 of substrate 110 and chip 120. More specifically, the upper surface and the flanks of chip 120 are protected by this element 150. The lower surface of chip 120 faces substrate 110.

Protective element 150 may be a layer of an insulating material 150, preferably a resin layer.

For example, the resin comprises at least one base material having electrically-insulating particles added thereto. The base material is selected, for example, from the group comprising: epoxy-type resins, and phenolic-type resins, acrylic-type resins. Preferably, it is an epoxy-type resin. The particles are, for example, oxide particles, and in particular alumina particles or silica particles.

The resin may be cured under an ultraviolet (UV) radiation or by thermal activation. An anneal may also be carried out.

The resin may be deposited by injection (‘molding’).

The resin is, for example, molded onto substrate 110 and chip 120.

Alternatively, protective element 150 is a cover 150, made of metal or of plastic, in contact or not with chip 120.

During step b), the various electronic components 100 are separated from one another. This step is carried out by cutting substrate 110 and resin layer 150 between chips 120.

This singulation step is carried out by means of a cutting device. The cutting device is, for example, a mechanical cutting tool such as a saw, or a laser or plasma etching tool. According to another embodiment, the cutting device is a laser.

During step c), hydrophobic coating 170 is formed.

Hydrophobic coating 170 is preferably a composite material comprising a polymer having fillers dispersed therein. The fillers are preferably non-conductive.

The fillers may be made of ceramic or of a carbon material such as graphene.

Oxide fillers, preferably alumina, yttrium oxide, zirconia, or silica fillers will in particular be selected.

Alternatively, metal-organic complexes or complexes of transition metals may be used.

Hydrophobic coating 170 has a thickness in the range from 2 nm to 20 μm.

The coating may be deposited in gaseous or liquid phase. The liquid phase may contain an organic solvent.

Preferably, before forming coating 170, a drying (‘bake’) step is carried out, for example at a temperature in the range from 80 to 140° C., preferably from 90 to 130° C. This step enables to remove all traces of humidity before forming hydrophobic coating 170.

When coating 170 is deposited on element 1000 (FIG. 2B), the flanks of electronic components 100 will not be covered by hydrophobic coating 170 during step b). Only the first side (front) and the second side (back) of the components can be covered by hydrophobic coating 170 during this step.

When hydrophobic coating 170 is deposited on the singulated electronic components 100 (FIG. 1D and FIG. 3C), it may be deposited on the first side, the second side, and the flanks of each electronic component 100. This type of application results in an improved protection against humidity. It is possible to form the hydrophobic coating in a plurality of steps, for example by forming the coating on the front side and then on the back side, or conversely. The flanks may be coated with the coating at the same time as the front side or at the same time as the back side.

During step d), electric connection pads 160 are bonded to electric connection terminals 140.

Connection pads 160 are, for example, bumps. The bumps have a diameter in the range from 50 μm to 900 μm, and preferably from 150 μm to 800 μm.

The electric connection pads are, for example, made of a tin alloy, preferably a tin-silver-copper alloy (SnAgCu or SAC).

This step may be carried out by soldering.

The solder material may be previously deposited on connection terminals 140. It may be deposited by using a printing technique, preferably by screen printing. Any additive deposition technique may be used. The solder material may be made of Sn, or a tin alloy such as SnAgCu or SnAg, or another alloy with a higher melting point.

During step e), hydrophobic coating 170 is locally removed to expose electric connection pads 160 and/or electric connection terminals 170.

This step may be carried out by chemical etching, by means of a masking step.

A step of mechanical removal may also be carried out, in the case where part of the coating 170 positioned on pads 160 is desired to be removed. This embodiment is advantageous in the case of pads 160 of large dimensions (typically of a dimension greater than 350 μm in diameter).

At the end of the method, electronic components 100 each comprise a substrate 110, one or a plurality of chips 120 arranged on a first side 111 of the substrate, a resin 150 covering substrate 110 and chip(s) 120, electric connection terminals 140 arranged on a second side 112 of substrate 110. Electric tracks 130 electrically couple chip 120 to electric connection terminals 140. A hydrophobic coating 170 covers at least protective element 150 and the second side 112 of substrate 110 between electric connection terminals 140. Hydrophobic coating 170 may also cover the sides of electronic component 100.

Connection pads 160 may be bonded to electric connection terminals 140.

Such components 100 may be bonded to an external device, for example a printed circuit board or other component.

These electronic components 100 have applications in many industrial fields and, in particular, in the automotive, aerospace field or the naval field (especially for a use onboard/in boats) or for devices intended to be placed in humid rooms, such as bathrooms, in underground locations, outdoors.

Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing a hydrophobic electronic component, comprising a step during which a hydrophobic coating is deposited on an electronic component, said electronic component comprising a substrate, a chip positioned on a first side of the substrate, electric connection terminals positioned on a second side of the substrate and electrically coupled to the chip using electric tracks running through the substrate, and a resin or a cover covering the first side of the substrate and the chip.

2. The method according to claim 1, comprising the following steps:
providing an element comprising a plurality of electronic components;
separating the electronic components;
bonding electric connection pads to the electric connection terminals; and
depositing the hydrophobic coating to fully cover the electronic component.

3. The method according to claim 2, further comprising a subsequent step during which the hydrophobic coating deposited on the electric connection pads is removed.

4. The method according to claim 2, wherein the electric connection pads are protected during the deposition of the hydrophobic coating.

5. The method according to claim 1, comprising the following steps:
providing an element comprising a plurality of electronic components;
depositing the hydrophobic coating so as to cover the resin or the cover and the second side of the substrate;
carrying out a step during which the hydrophobic coating deposited on the electric terminals is removed;
optionally, bonding electric connection pads to the electric terminals; and
separating the electronic components.

6. The method according to claim 1, comprising the following steps:
providing an element comprising a plurality of electronic components;
separating the electronic components;
depositing the hydrophobic coating so as to fully cover the electronic component;
carrying out a step during which the hydrophobic coating deposited on the electric terminals is removed; and
optionally, bonding electric connection pads to the electric terminals.

7. The method according to claim 1, wherein the hydrophobic coating is a composite comprising a polymer material having fillers dispersed therein.

8. The method according to claim 7, wherein the fillers are made of a ceramic or graphene.

9. The method according to claim 7, wherein the fillers are made of alumina or silica.

10. The method according to claim 1, wherein the substrate is made of a resin.

11. The method according to claim 1, wherein the substrate is made of a composite material comprising fillers.

12. The method according to claim 11, wherein the fillers comprise glass fibers, dispersed in a resin.

13. A method of manufacturing a hydrophobic electronic component, comprising steps performed in the following order:
providing an element comprising a plurality of chips mounted to a first side of a substrate and covered by a resin covering;
wherein a second side of the substrate includes electric connection terminals connected to the chips by electric tracks running through the substrate;
bonding electric connection pads to the electric connection terminals;
separating said element into a plurality of electronic components; and
depositing a hydrophobic coating covering a first side, a second side and flanks of each electronic component.

14. The method of claim 13, further comprising:
removing a portion of said hydrophobic coating which covers the electric connection pads.

15. The method of claim 13, further comprising protecting the electric connection pads using a protective element before depositing the hydrophobic coating and removing the protective element after depositing the hydrophobic coating.

16. An electronic component, comprising:
a substrate;
a chip positioned on a first side of the substrate;
wherein electric connection terminals are positioned on a second side of the substrate and electrically coupled to the chip using electric tracks running through the substrate;
a resin or a cover covering the first side of the substrate and the chip; and
a hydrophobic coating covering at least the resin or the cover and the second side of the substrate between the electric connection terminals.

17. The component according to claim 16, wherein the hydrophobic coating is a composite comprising a polymer material having fillers dispersed therein.

18. The component according to claim 17, wherein the fillers are made of ceramic or graphene.

19. The component according to claim 17, wherein the fillers are made of alumina or silica.

20. The component according to claim 16, wherein the substrate is made of a resin.

21. The component according to claim 16, wherein the substrate is made of a composite material comprising fillers.

22. The component according to claim 21, wherein the fillers comprise glass fibers, dispersed in a resin.
